(19) United States
(12) Patent Application Publication
(10) Pub. No.: US 2026/0271217 A1
(43) Pub. Date: Sep. 10, 2026

(54) RACK AND SUPPORTING TRAY ASSEMBLY

(71) Applicants: INVENTEC (PUDONG) TECHNOLOGY CORPORATION, Shanghai (CN); INVENTEC CORPORATION, Taipei City (TW)

(72) Inventors: Kai CHUANG, Taipei City (TW); Ming Tsung LIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/316,398

(22) Filed: Sep. 2, 2025

(30) Foreign Application Priority Data
Mar. 6, 2025 (CN) 202510264088.6

(51) Int. Cl. H05K 7/14

(52) U.S. Cl. CPC H05K 7/1492; H05K 7/1401

(57) ABSTRACT

A rack is configured to support a server, and includes a rack body and a supporting tray assembly. The supporting tray assembly includes a supporting component and a quick-release bracket. The supporting component is movably assembled on the rack body, and includes a bottom plate and two side plates. The two side plates are connected to two opposite sides of the bottom plate, respectively. The bottom plate and the two side plates form a first accommodating space. The quick-release bracket is detachably disposed on the two side plates, respectively, and is located between the two side plates. The bottom plate, at least one of the two side plates and the quick-release bracket form a second accommodating space. A size of the first accommodating space is greater than a size of the second accommodating space. The first accommodating space or the second accommodating space are configured to accommodate the server.

### CROSS-REFERENCE TO RELATED APPLICATIONS

This non-provisional application claims priority under 35 U.S.C. § 119(a) on Patent Application No(s). 202510264088.6 filed in China, on March 6th, 2025, the entire contents of which are hereby incorporated by reference.

### BACKGROUND OF THE INVENTION

### Technical Field of the Invention

The invention relates to a rack and a supporting tray assembly, more particularly to a rack and a supporting tray assembly having at least one quick-release bracket.

### Description of the Related Art

Nowadays, the information technology is under rapid development and personal computers are indispensable for corporations and individuals when handling various tasks. As communication technology becomes highly developed, the regional business transaction being replaced by transnational electronic commerce has become a trend, and the transnational electronic commerce involves massive data computation that typical personal computers are unable to deal with. Therefore, the data center employs various forms of server systems, such as rack server system, blade server system, and tower server system, to provide e-commerce services for users.

For example, the rack server will be described below. Generally, servers may be assembled in a rack via angle iron brackets. However, the angle iron brackets provide limited supporting region, which may result in insufficient support strength for the servers. In addition, when the servers of different sizes are required to be assembled in the rack, the angle iron brackets are required to be replaced accordingly, thereby causing inconvenience in assembly. Moreover, shorter servers may be difficult to be plugged into a busbar disposed in the rack via the aforementioned assembling structure. Therefore, improving the convenience of the assembly of the server and the rack and enhancing the assembling strength between the server and the rack is one of the key issues that researchers need to address.

### SUMMARYOF THE INVENTION

The invention provides a rack and a supporting tray assembly so as to improve the convenience of the assembly of a server and a rack body and enhancing the assembling strength between the server and the rack body.

One embodiment of the invention provides a rack configured to support at least one server. The rack includes a rack body and at least one supporting tray assembly. The at least one supporting tray assembly includes a supporting component and at least one quick-release bracket. The supporting component is movably assembled on the rack body, and includes a bottom plate and two side plates. The two side plates are connected to two opposite sides of the bottom plate, respectively. The bottom plate and the two side plates together form a first accommodating space. The at least one quick-release bracket is detachably located between the two side plates. The bottom plate, at least one of the two side plates and the at least one quick-release bracket together form a second accommodating space. A size of the first accommodating space is greater than a size of the second accommodating space. The first accommodating space or the second accommodating space are configured to accommodate the at least one server.

Another embodiment of the invention provides a supporting tray assembly configured to be disposed in a rack and accommodate at least one server. The supporting tray assembly includes a supporting component and at least one quick-release bracket. The supporting component is configured to be movably assembled on the rack body, and includes a bottom plate and two side plates. The two side plates are connected to two opposite sides of the bottom plate, respectively. The bottom plate and the two side plates together form a first accommodating space. The at least one quick-release bracket is detachably located between the two side plates. The bottom plate, at least one of the two side plates and the at least one quick-release bracket together form a second accommodating space. A size of the first accommodating space is greater than a size of the second accommodating space. The first accommodating space or the second accommodating space are configured to accommodate the at least one server.

According to the rack and the supporting tray assembly disclosed in the above embodiment, the at least one quick-release bracket is detachably disposed on the two side plates, respectively, and are located between the two side plates of the supporting component. Therefore, when the at least one quick-release bracket is assembled on the supporting component, the server of a first size can be assembled on the supporting component. Alternatively, when the at least one quick-release bracket is removed from the supporting component, the server of a second size different from the first size can be assembled on the supporting component. That is, the supporting tray assembly can be compatible with the servers of different sizes without changing trays of different sizes according to the size of the servers. Accordingly, the convenience of the assembly of the server and the rack body can be improved.

In addition, compared with supporting the server via angle iron brackets, in this embodiment, the server is supported on the bottom plate, such that the supporting region of the supporting member is larger than the supporting region of the angle iron brackets. Therefore, the server can be assembled on the supporting tray assembly more firmly, thereby enhancing the assembling strength of the assembly of the server.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of a rack in accordance with a first embodiment of the invention;

FIG. 2 is an enlarged cross-sectional view of the rack in FIG. 1;

FIG. 3 is an exploded view of a supporting tray assembly and a server of the rack in FIG. 1;

FIG. 4 is an enlarged exploded view of the supporting tray assembly of the rack in FIG. 1;

FIG. 5 is a perspective view of the rack in FIG. 1 showing that one of quick-release brackets is assembled on a supporting component;

FIG. 6 is another perspective view of the rack in FIG. 1 showing that one of the quick-release brackets is assembled on the supporting component;

FIG. 7 is another perspective view of the rack in FIG. 1 showing that one of the quick-release brackets is assembled on the supporting component;

FIG. 8 is a cross-sectional view of the rack in FIG. 1 showing that the supporting tray assembly is assembled in a rack body;

FIG. 9 is another cross-sectional view of the rack in FIG. 1 showing that the supporting tray assembly is assembled in the rack body;

FIG. 10 is a perspective view of a supporting tray assembly in accordance with a second embodiment of the invention;

FIG. 11 is a perspective view of a supporting tray assembly in accordance with a third embodiment of the invention; and

FIG. 12 is a perspective view of a supporting tray assembly and a server in accordance with a fourth embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

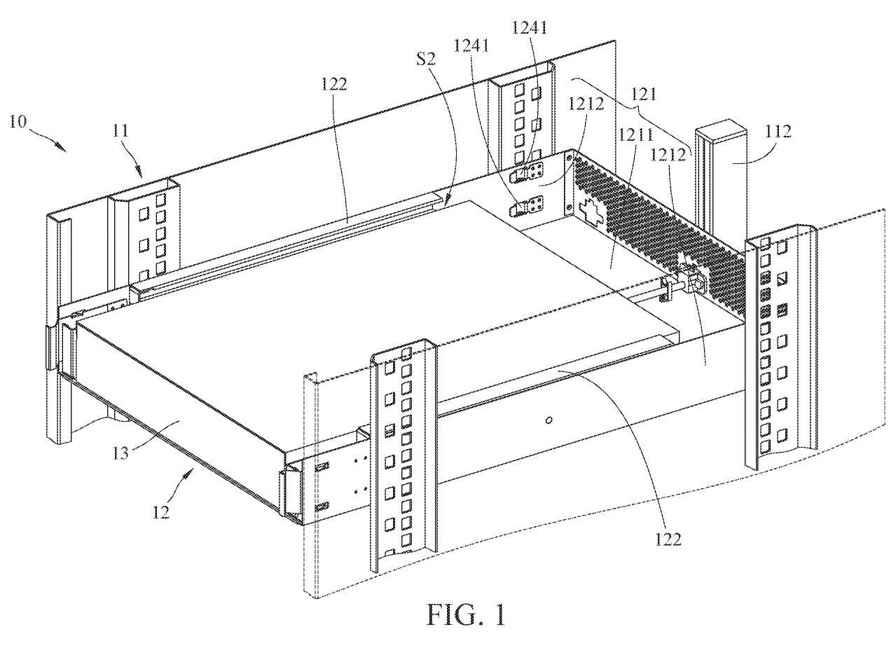

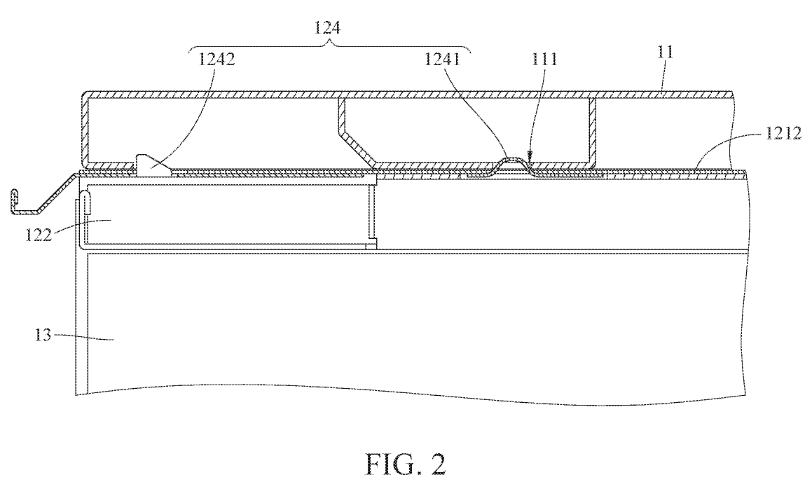

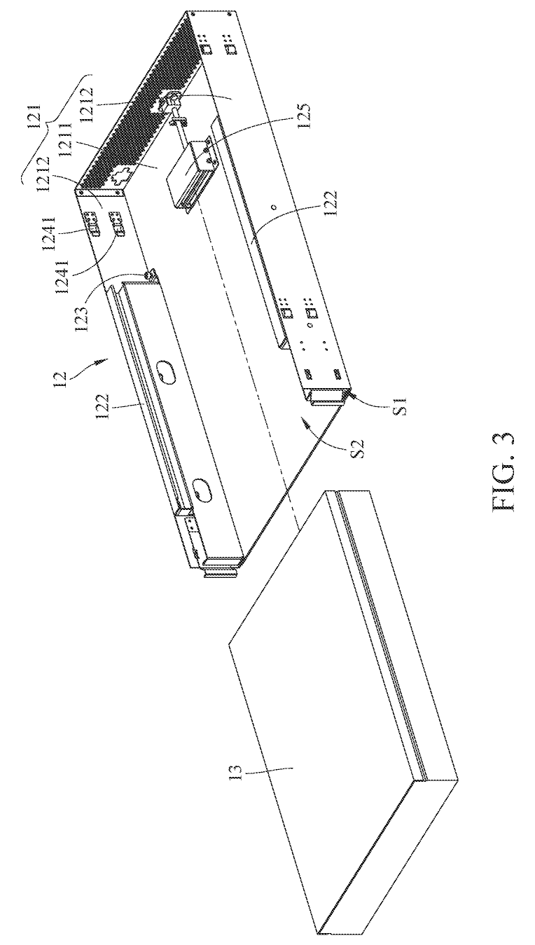

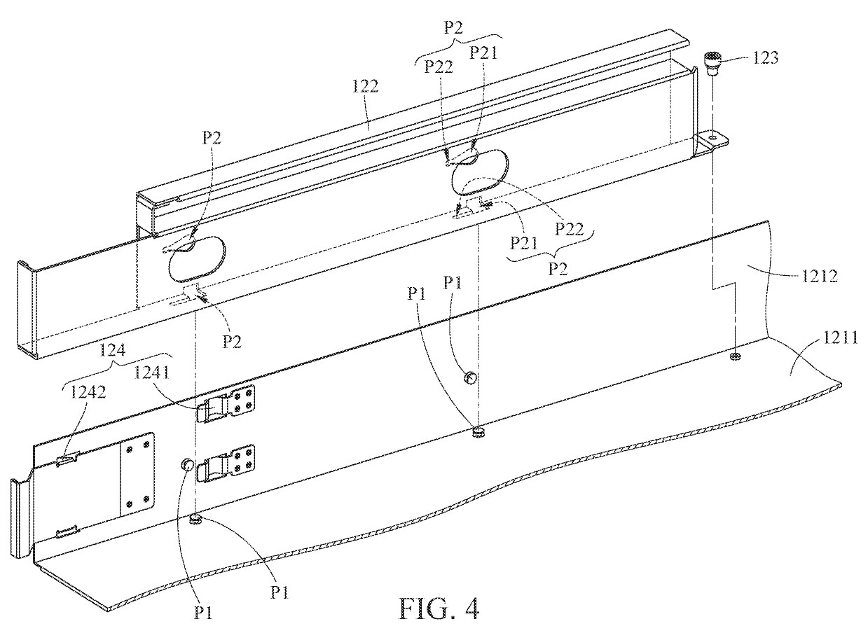

Please refer to FIG. 1 and FIG. 4, where FIG. 1 is a perspective view of a rack 10 in accordance with a first embodiment of the invention, FIG. 2 is an enlarged cross-sectional view of the rack 10 in FIG. 1, FIG. 3 is an exploded view of a supporting tray assembly 12 and a server 13 of the rack 10 in FIG. 1, and FIG. 4 is an enlarged exploded view of the supporting tray assembly 12 of the rack 10 in FIG. 1.

In this embodiment, the rack 10 is configured to support at least one server 13, and includes a rack body 11 and a supporting tray assembly 12. The supporting tray assembly 12 includes a supporting component 121, two quick-release brackets 122 and two fasteners 123. The supporting component 121 is movably assembled on the rack body 11, and includes a bottom plate 1211 and two side plates 1212. The two side plates 1212 are connected to two opposite sides of the bottom plate 1211, respectively. The quick-release brackets 122 are detachably disposed on the two side plates 1212, respectively, and are located between the two side plates 1212. The quick-release brackets 122 are detachably disposed on the bottom plate 1211 via the fasteners 123. The fasteners 123 are, for example, captive screws.

Furthermore, each of the bottom plate 1211 and the side plates 1212 includes a plurality of first positioning structures P1, and each of the quick-release brackets 122 includes a plurality of second positioning structures P2. For example, the first positioning structures P1 are positioning protrusions, and the second positioning structures P2 are positioning holes. Each of the second positioning structures P2 includes a wide portion P21 and a narrow portion P22. The wide portion P21 is connected to the narrow portion P22. A width of the wide portion P21 is greater than a width of the narrow portion P22. The first positioning structures P1 is slidably disposed in the second positioning structures P2, respectively, and are located at the wide portions P21 or the narrow portions P22, respectively. When the first positioning structures P1 are respectively located at the wide portions P21, the quick-release brackets 122 are released from the supporting component 121. When the first positioning structures P1 are respectively located at the narrow portions P22, the quick-release brackets 122 are held in position on the supporting component 121.

The bottom plate 1211 and the side plates 1212 together form a first accommodating space S1, and the bottom plate 1211, the side plates 1212 and the quick-release brackets 122 together form a second accommodating space S2. A size of the first accommodating space S1 is greater than a size of the second accommodating space S2. The first accommodating space S1 or the second accommodating space S2 are configured to accommodate the at least one server 13. In this embodiment, the server 13 has a size of, for example, 19 inches. The quick-release brackets 122 are disposed on the supporting component 121, such that the server 13 is disposed in the second accommodating space S2. In addition, a height of the server 13 is, for example, 2U.

In this embodiment, the supporting tray assembly 12 may include a plurality of engaging components 124. Each of the engaging components 124 includes a plurality of first engaging portions 1241 and a blocking portion 1242. The first engaging portions 1241 and the blocking portion 1242 are disposed on the side plate 1212. The first engaging portions 1241 are, for example, engaging protrusions. The rack body 11 includes a plurality of second engaging portions 111. The second engaging portions 111 are, for example, engaging holes. The first engaging portions 1241 are configured to be respectively engaged with the second engaging portions 111, and the blocking portion 1242 is configured to contact with the rack body 11, such that the supporting tray assembly 12 is held in position in the rack body 11. For example, the engaging components 124 are cantilevers made of stainless steel, and is riveted to the side plates 1212, respectively.

In this embodiment, the supporting tray assembly 12 may include a power assembly 125. The power assembly 125 is disposed on the bottom plate 1211, and may include a junction box and at least one power connector. The at least one power connector is disposed in the junction box. The rack body 11 includes a busbar 112. The server 13 is electrically connected to the busbar 112 via the power assembly 125. For example, the server 13 is plugged into the power assembly 125, and the power assembly 125 is electrically connected to the busbar 112 via cables (not shown).

In this embodiment, the quick-release brackets 122 are detachably disposed on the two side plates 1212, respectively, and are located between the two side plates 1212 of the supporting component 121. Therefore, when the quick-release brackets 122 are assembled on the supporting component 121, the server of a first size can be assembled on the supporting component 121. Alternatively, when the quick-release brackets 122 are removed from the supporting component 121, the server of a second size different from the first size can be assembled on the supporting component 121. That is, the supporting tray assembly 12 can be compatible with the servers of different sizes without changing trays of different sizes according to the size of the servers. Accordingly, the convenience of the assembly of the server 13 and the rack body 11 can be improved.

In addition, since the supporting tray assembly 12 is assembled on the rack body 11 via the engaging components 124 without using assembling tools additionally, the convenience of assembling the server 13 in the rack body 11 can be further improved.

In addition, compared with supporting the server via angle iron brackets, in this embodiment, the server 13 is supported on the bottom plate 1211, such that the supporting region of the supporting component 121 is larger than the supporting region of the angle iron brackets. Therefore, the server 13 can be assembled on the supporting tray assembly 12 more firmly, thereby enhancing the assembling strength of the assembly of the server 13.

Moreover, the supporting component 121 has a large supporting region. Therefore, the supporting component 121 provides a sufficient space for the power assembly 125 to be additionally assembled, such that the server 13 can be facilitated to be electrically connected to the busbar 112. Accordingly, the convenience of the assembly of the server 13 and the rack body 11 can be further improved.

In this embodiment, there are one supporting tray assembly 12 and one server 13, but the invention is not limited thereto. In other embodiments, there may be multiple supporting tray assemblies and multiple servers.

In this embodiment, there are two quick-release brackets 122, and the bottom plate 1211, the two side plates 1212 and the two quick-release brackets 122 together form the second accommodating space S2, but the invention is not limited thereto. In other embodiments, there may be one quick-release bracket, and the bottom plate, at least one of the two side plates and the quick-release bracket may together form the second accommodating space.

In this embodiment, each of the bottom plate 1211 and the side plates 1212 includes the first positioning structures P1, but the invention is not limited thereto. In other embodiments, the bottom plate or the side plates may include the first positioning structures.

In this embodiment, there are multiple first positioning structures P1 and multiple second positioning structures P2, but the invention is not limited thereto. In other embodiments, there may be one first positioning structure and one second positioning structure.

In this embodiment, there are multiple engaging components 124, but the invention is not limited thereto. In other embodiments, there may be one engaging component.

In this embodiment, there are multiple first engaging portions 1241 in each of the engaging components 124 and multiple second engaging portions 111 in the rack body 11, and there is one blocking portion 1242 in each of the engaging components 124, but the invention is not limited thereto. In other embodiments, there may be one first engaging portion in each of the engaging components and one second engaging portion in the rack body, and there may be multiple blocking portions in each of the engaging components.

In this embodiment, the first positioning structures P1 are positioning protrusions, and the second positioning structures P2 are positioning holes, but the invention is not limited thereto. In other embodiments, the protrusion and hole configurations of the first positioning structures and the second positioning structures may be exchanged. That is, the first positioning structures may be positioning holes, and the second positioning structures may be positioning protrusions.

In this embodiment, the first engaging portions 1241 are engaging protrusions, and the second engaging portions 111 are engaging holes, but the invention is not limited thereto. In other embodiments, the protrusion and hole configurations of the first engaging portions and the second engaging portions may be exchanged. That is, the first engaging portions may be engaging holes, and the second engaging portions may be engaging protrusions.

In this embodiment, the supporting tray assembly 12 includes the power assembly 125, and the server 13 is electrically connected to the busbar 112 via the power assembly 125, but the invention is not limited thereto. In other embodiments, the supporting tray assembly may not include the power assembly, and the server may be electrically connected to the busbar via, for example, cables or other manners.

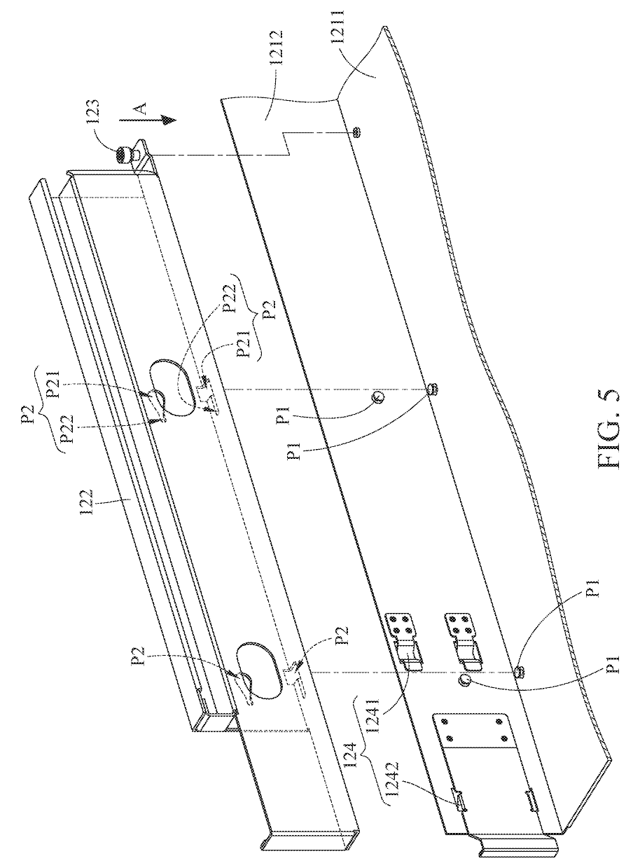

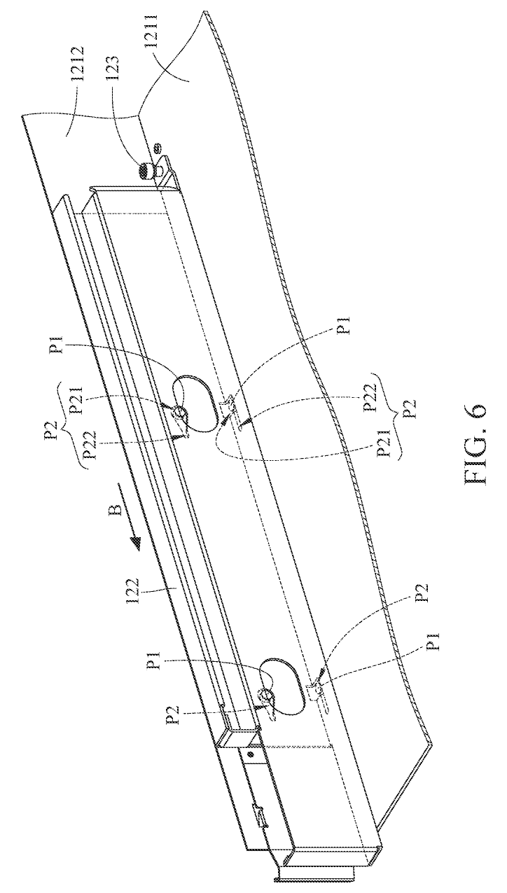

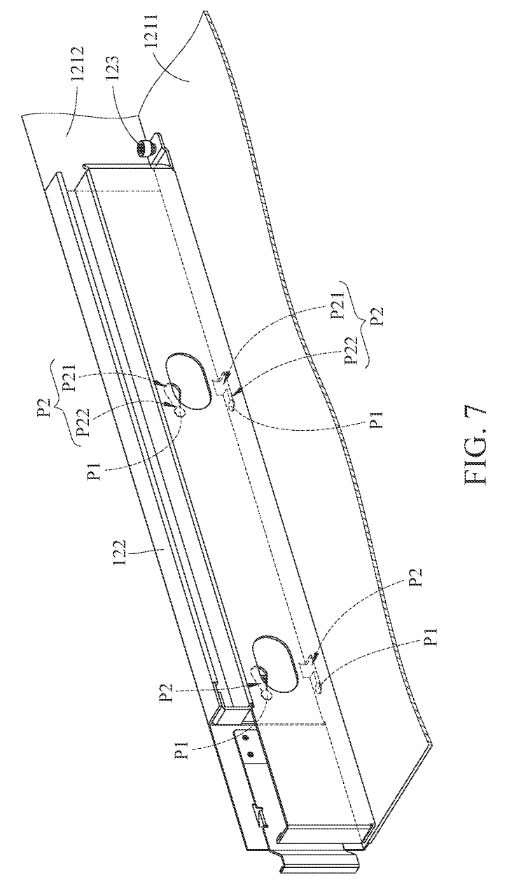

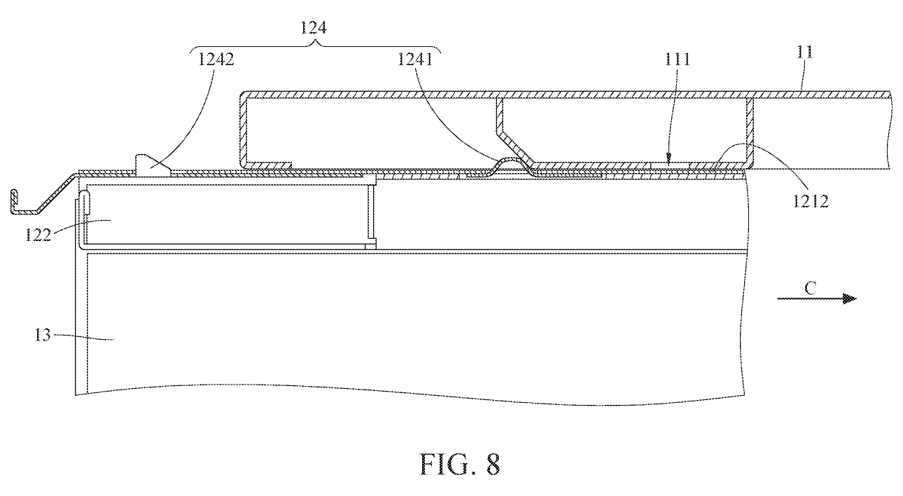

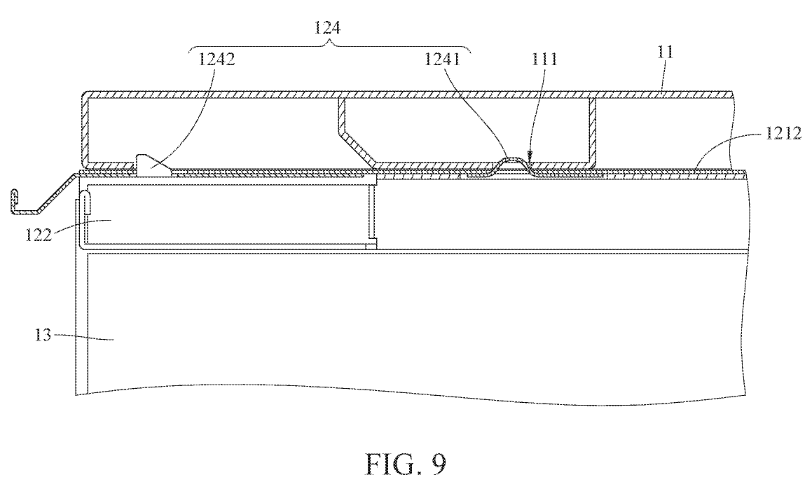

Please refer to FIG. 1 and FIG. 9, where FIG. 5 is a perspective view of the rack 10 in FIG. 1 showing that one of the quick-release brackets 122 is assembled on the supporting component 121, FIG. 6 is another perspective view of the rack 10 in FIG. 1 showing that one of the quick-release brackets 122 is assembled on the supporting component 121, FIG. 7 is another perspective view of the rack 10 in FIG. 1 showing that one of the quick-release brackets 122 is assembled on the supporting component 121, FIG. 8 is a cross-sectional view of the rack 10 in FIG. 1 showing that the supporting tray assembly 12 is assembled in the rack body 11, and FIG. 9 is another cross-sectional view of the rack 10 in FIG. 1 showing that the supporting tray assembly 12 is assembled in the rack body 11.

Only the assembly of one quick-release bracket 122 and one fastener 123 will be described below. When the supporting tray assembly 12 is required to be assembled in the rack body 11, firstly, as shown in FIG. 5 and FIG. 6, the quick-release bracket 122 is assembled on the supporting component 121 along a direction A, such that the first positioning structures P1 are disposed at the wide portions P21, respectively. Then, as shown in FIG. 6 and FIG. 7, the quick-release bracket 122 is moved along a direction B, such that the first positioning structures P1 are moved from the wide portions P21 to the narrow portions P22 along the direction B, respectively. Accordingly, the quick-release bracket 122 can be held in position on the supporting component 121. Then, the quick-release bracket 122 is fixed to the bottom plate 1211 via the fastener 123, such that the quick-release bracket 122 can be assembled on the supporting component 121.

Only the assembly of one engaging component 124 and one second engaging portion 111 will be described below. Then, the supporting component 121 is assembled in the rack body 11 along a direction C, such that the first engaging portion 1241 is engaged with the second engaging portion 111. In addition, the blocking portion 1242 contacts with the rack body 11, such that the supporting tray assembly 12 is held in position in the rack body 11. Accordingly, the supporting tray assembly 12 can be assembled in the rack body 11. Since the blocking portion 1242 contacts with the rack body 11, the supporting tray assembly 12 can be prevented from falling off the rack body 11 along a direction opposite to the direction C.

On the contrary, when the supporting tray assembly 12 is required to be removed from the rack body 11, the first engaging portion 1241 is released from the second engaging portion 111 and the blocking portion 1242 is released from the rack body 11 by pressing the engaging component 124. Accordingly, the supporting component 121 can be removed from the rack body 11 along the direction opposite to the direction C. In addition, when the quick-release bracket 122 is required to be removed from the supporting component 121, the quick-release bracket 122 is moved along a direction opposite to the direction B, such that the first positioning structures P1 are moved from the narrow portions P22 to the wide portions P21 along a direction opposite to the direction B, respectively. Accordingly, the quick-release bracket 122 can be removed from the supporting component 121 along a direction opposite to the direction A.

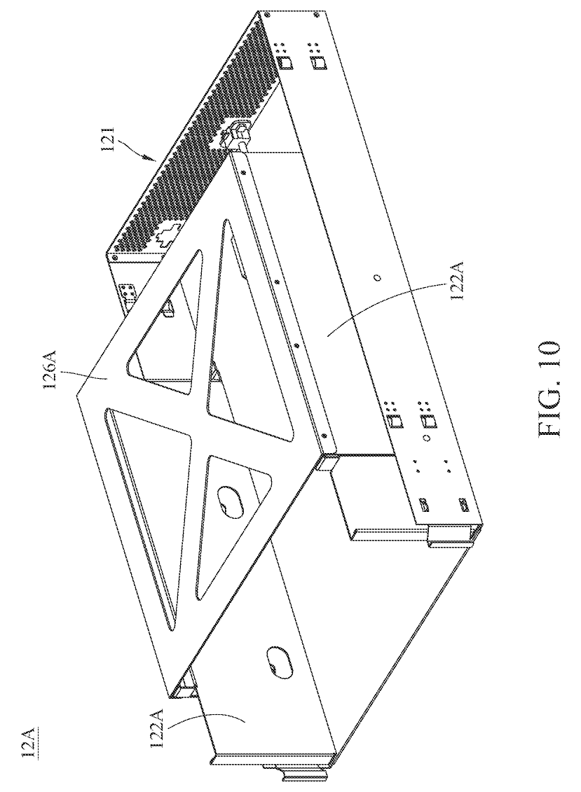

Please refer to FIG. 10, which is a perspective view of a supporting tray assembly 12A in accordance with a second embodiment of the invention. The supporting tray assembly 12A of this embodiment is similar to the supporting tray assembly 12 of the first embodiment, the main difference between them will be described below, and the same parts between them can be referred to the aforementioned paragraphs with the reference to FIG. 1 to FIG. 9 and will not be repeatedly introduced hereinafter.

In this embodiment, a height of a server (not shown) is, for example, 4U, and the server is higher than a supporting component 121. Therefore, the supporting tray assembly 12A may include a reinforcing frame 126A, and a height of quick-release brackets 122A is adjusted according to the height of the server. The reinforcing frame 126A is detachably assembled on the quick-release brackets 122A, and covers the server. Accordingly, the support for the server can be reinforced, such that the server is assembled on the supporting tray assembly 12A more firmly.

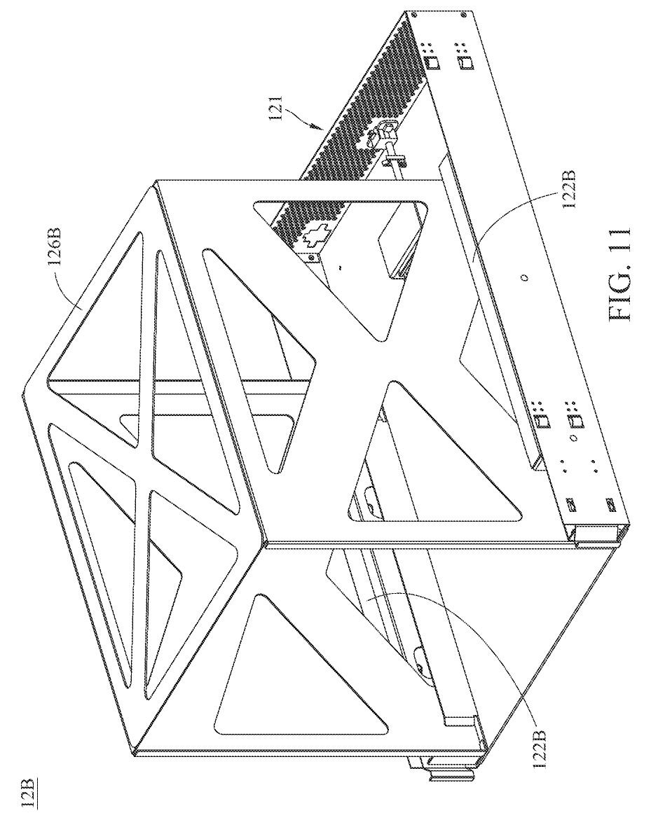

Please refer to FIG. 11, which is a perspective view of a supporting tray assembly 12B in accordance with a third embodiment of the invention. The supporting tray assembly 12B of this embodiment is similar to the supporting tray assembly 12 of the first embodiment, the main difference between them will be described below, and the same parts between them can be referred to the aforementioned paragraphs with the reference to FIG. 1 to FIG. 9 and will not be repeatedly introduced hereinafter.

In this embodiment, a height of a server (not shown) is, for example, 12U, and the server is higher than a supporting component 121. Therefore, the supporting tray assembly 12B may include a reinforcing frame 126B. The reinforcing frame 126B is detachably assembled on the quick-release brackets 122B, and covers the server. Accordingly, the support for the server can be reinforced, such that the server is assembled on the supporting tray assembly 12B more firmly.

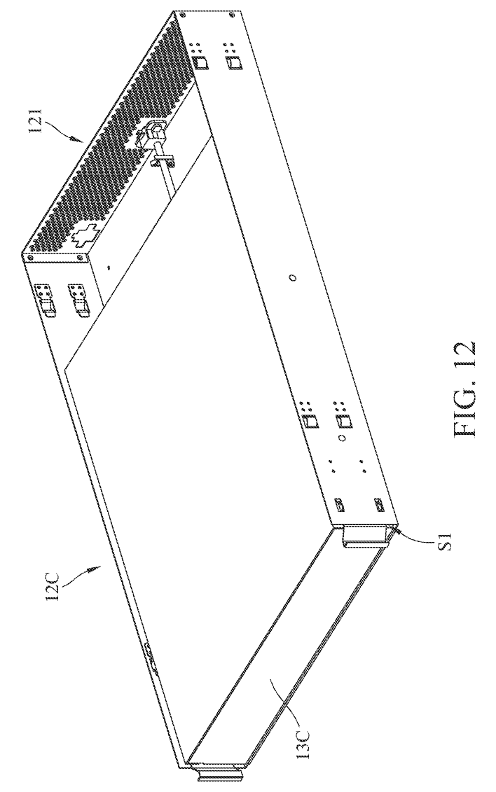

Please refer to FIG. 12, which is a perspective view of a supporting tray assembly 12C and a server 13C in accordance with a fourth embodiment of the invention. The supporting tray assembly 12C and the server 13C of this embodiment is similar to the supporting tray assembly 12 and the server 13 of the first embodiment, the main difference between them will be described below, and the same parts between them can be referred to the aforementioned paragraphs with the reference to FIG. 1 to FIG. 9 and will not be repeatedly introduced hereinafter.

In this embodiment, the server 13C has a size of, for example, 21 inches. That is, a size of the server 13C of this embodiment is greater than a size of the server 13 of the first embodiment. Therefore, in this embodiment, the server 13C is configured to be disposed in the first accommodating space S1 directly without assembling the quick-release brackets on the supporting component 121.

According to the rack and the supporting tray assembly disclosed in the above embodiment, the quick-release brackets are detachably disposed on the two side plates, respectively, and are located between the two side plates of the supporting component. Therefore, when the quick-release brackets are assembled on the supporting component, the server of the first size can be assembled on the supporting component. Alternatively, when the quick-release brackets are removed from the supporting component, the server of the second size different from the first size can be assembled on the supporting component. That is, the supporting tray assembly can be compatible with the servers of different sizes without changing trays of different sizes according to the size of the servers. Accordingly, the convenience of the assembly of the server and the rack body can be improved.

In addition, since the supporting tray assembly is assembled on the rack body via the engaging components without using assembling tools additionally, the convenience of assembling the server in the rack body can be further improved.

In addition, compared with supporting the server via angle iron brackets, in this embodiment, the server is supported on the bottom plate, such that the supporting region of the supporting member is larger than the supporting region of the angle iron brackets. Therefore, the server can be assembled on the supporting tray assembly more firmly, thereby enhancing the assembling strength of the assembly of the server.

Moreover, the supporting component has a large supporting region. Therefore, the supporting component provides a sufficient space for the power assembly to be additionally assembled, such that the server can be facilitated to be electrically connected to the busbar. Accordingly, the convenience of the assembly of the server and the rack body can be further improved.

In this embodiment, the rack and the supporting tray assembly of the invention can be applied to a server. The server can apply artificial intelligence (AI) computing, edge computing, and can also be used as a 5G server, a cloud server or a Vehicle-to-everything server.

It will be apparent to those skilled in the art that various modifications and variations can be made to the invention. It is intended that the specification and examples be considered as exemplary embodiments only, with the scope of the invention being indicated by the following claims.

What is claimed is:

1. A rack, configured to support at least one server, and the rack comprising:
a rack body; and
at least one supporting tray assembly, comprising:
a supporting component, movably assembled on the rack body and comprising a bottom plate and two side plates, wherein the two side plates are connected to two opposite sides of the bottom plate, respectively, and the bottom plate and the two side plates together form a first accommodating space, and
at least one quick-release bracket, detachably disposed on the two side plates, respectively and located between the two side plates, wherein the bottom plate, at least one of the two side plates and the at least one quick-release bracket together form a second accommodating space, a size of the first accommodating space is greater than a size of the second accommodating space, and the first accommodating space or the second accommodating space are configured to accommodate the at least one server.

2. The rack according to claim 1, wherein the bottom plate or the two side plates comprise at least one first positioning structure, the at least one quick-release bracket comprises at least one second positioning structure, the at least one second positioning structure comprises a wide portion and a narrow portion, the wide portion is connected to the narrow portion, a width of the wide portion is greater than a width of the narrow portion, the at least one first positioning structure is slidably disposed in the at least one second positioning structure and located at the wide portion or the narrow portion, when the at least one first positioning structure is located at the wide portion, the at least one quick-release bracket is released from the supporting component, and when the at least one first positioning structure is located at the narrow portion, the at least one quick-release bracket is held in position on the supporting component.

3. The rack according to claim 1, wherein the at least one supporting tray assembly further comprises a power assembly, the power assembly is disposed on the bottom plate, the rack body comprises a busbar, and the power assembly is configured for the at least one server to be electrically connected to the busbar.

4. The rack according to claim 1, wherein the at least one supporting tray assembly further comprises at least one engaging component, the at least one engaging component comprises at least one first engaging portion, the at least one first engaging portion is disposed on one of the two side plates, the rack body comprises at least one second engaging portion, and the at least one first engaging portion is configured to be engaged with the at least one second engaging portion to position the at least one supporting tray assembly on the rack body.

5. The rack according to claim 4, wherein the at least one engaging component further comprises at least one blocking portion, the at least one blocking portion is disposed on one of the two side plates, and the at least one blocking portion is configured to contact with the rack body.

6. The rack according to claim 1, wherein the at least one supporting tray assembly further comprises a fastener, and the at least one quick-release bracket is fixed to the bottom plate via the fastener.

7. The rack according to claim 1, wherein the at least one supporting tray assembly further comprises a reinforcing frame, the reinforcing frame is detachably assembled on the at least one quick-release bracket, and the reinforcing frame is configured to cover the at least one server.

8. A supporting tray assembly, configured to be disposed in a rack and accommodate at least one server, and the supporting tray assembly comprising:
a supporting component, configured to be movably assembled on the rack and comprising a bottom plate and two side plates, wherein the two side plates are connected to two opposite sides of the bottom plate, respectively, and the bottom plate and the two side plates together form a first accommodating space, and
at least one quick-release bracket, detachably disposed on the two side plates, respectively and located between the two side plates, wherein the bottom plate, at least one of the two side plates and the at least one quick-release bracket together form a second accommodating space, a size of the first accommodating space is greater than a size of the second accommodating space, and the first accommodating space or the second accommodating space are configured to accommodate the at least one server.

9. The supporting tray assembly according to claim 8, wherein the bottom plate or the two side plates comprise at least one first positioning structure, the at least one quick-release bracket comprises at least one second positioning structure, the at least one second positioning structure comprises a wide portion and a narrow portion, the wide portion is connected to the narrow portion, a width of the wide portion is greater than a width of the narrow portion, the at least one first positioning structure is slidably disposed in the at least one second positioning structure and located at the wide portion or the narrow portion, when the at least one first positioning structure is located at the wide portion, the at least one quick-release bracket is released from the supporting component, and when the at least one first positioning structure is located at the narrow portion, the at least one quick-release bracket is held in position on the supporting component.

10. The supporting tray assembly according to claim 8, further comprising a power assembly, wherein the power assembly is disposed on the bottom plate, and the power assembly is configured for the at least one server to be electrically connected to a busbar of the rack.
